(19) United States
(12) Patent Application Publication
(10) Pub. No.: US 2025/0031482 A1
(43) Pub. Date: Jan. 23, 2025

(54) Protective Coating for Solar Cells

(71) Applicant: Oakwood University, Inc., Huntsville, AL (US)

(72) Inventors: Darayas Nanabhoy Patel, Madison, AL (US); Sergey Sergevevich Sarkisov, Huntsville, AL (US); Alexandre Iwan Fedoseyev, Madison, AL (US)

(73) Assignee: Oakwood University, Inc., Huntsville, AL (US)

(21) Appl. No.: 18/764,466

(22) Filed: Jul. 5, 2024

Related U.S. Application Data
(60) Provisional application No. 63/628,411, filed on Jul. 17, 2023.

(51) Int. Cl. H01L 31/0216; H01L 31/18

(52) U.S. Cl. CPC H01L 31/02168; H01L 31/18

(57) ABSTRACT

A protective coating for solar cells and the method of its making. The coating consists of four sub-coatings: the first, second, and the third polymer nanocomposite coatings and the optical anti-reflection coating on the top. The anti-reflection coating minimizes the reflection of the incident sun light and is made by embedding silica nanoparticles in the third coating. The third coating protects the solar cell for the low-orbit atomic oxygen and transmits the sunlight further down. The second polymer nanocomposite coating is composed of a colorless polymer embedded with the nanoparticles of a compound absorbing sun UV radiation and converting it into visible and NIR radiation suitable for generating electricity by the cell. The first nanocomposite layer is made of a colorless polymer nanocomposite blocking the residual harmful UV and atomic oxygen from reaching the cell and shortening its operational lifetime.

### CROSS-REFERENCE TO RELATED APPLICATIONS

This application claims priority to U.S. Provisional Patent Application Ser. No. 63/628,411 entitled Polymer Nanocomposite for Protecting Photovoltaic Cells filed on Jul. 14, 2024, which is incorporated herein by reference.

### BACKGROUND

Solar cells (also known as photovoltaic (PV) cells) are used in space applications to provide power (electricity) to space equipment. A solar cell converts solar radiation directly into electricity.

Space is a harsh environment, and equipment in space is exposed to ultraviolet (UV) sun radiation, cosmic radiation, and low-orbit atomic oxygen (AO). Both types of radiation and AO lead to the premature degradation of the solar cells and shorten their operational lifetime. As a result, duration of space missions may be shortened, or the cells must be often replaced, and the cost of the mission may stay high.

### DESCRIPTION OF THE FIGURES

FIG. 1 is a diagram of an exemplary solar cell in accordance with an embodiment of the present invention.

FIG. 2 is a flowchart of an exemplary method of manufacture of the solar cell of FIG. 1.

FIG. 3 is a diagram showing a principle of operation of the solar cell of FIG. 1.

FIG. 4 is a graph of size distribution of nanoparticles (NPs) by intensity (percentage) in operation of the solar cell of FIG. 1.

FIG. 5 is a graph of X-ray diffraction spectrum (intensity versus the diffraction angle in degrees) of the nano-powder consisted of the NPs.

FIG. 6 is an energy level diagram of an Eu³⁺ ion.

FIG. 7 is a graph of the optical reflectance spectrum (reflectance versus wavelength) of a compressed powder sample of NaEuF₄.

FIG. 8 is a graph of a photoluminescence (PL) spectrum of NaEuF₄ powder sample pumped by a 372-nm UV diode laser Oxxius (71.3 mW/cm² irradiance), (2) the polymer nanocomposite coating over a solar cell illuminated by a 365-nm UV LED (22.3 mW/cm² irradiance). The spectrum of the UV LED simulated the UV-A spectral component of Sun radiation.

FIG. 9 is a graph of a photoluminescence (PL) spectrum of NaEuF₄ powder in FIG. 8. Curve 1 is the spectrum of the normalized Incident-Photon-to-Current Efficiency (IPCE, also called External Quantum Efficiency or EQE) of an Inverted Metamorphic Multijunction (IMM) solar cell, curve 2—the IPCE spectrum of a Silicon Hetero Junction (SHJ) cell, and 3—the IPCE spectrum of a Copper-Indium-Gallium-Selenide (CIGS) cell.

### DETAILED DESCRIPTION

An exemplary solar cell of the present disclosure comprises a polymer nanocomposite protective layer comprising spectrum converting nanoparticles (NPs) embedded in a colorless polymer. The nanocomposite protective layer is deposited on the top of a solar photovoltaic cell. Both ultraviolet (UV) and visible (and near-infrared, NIR) components of solar radiation reach the layer. The UV component is absorbed by the NPs and spectrally converted into visible (and NIR) radiation. The extra visible (and NIR)) radiation produced by the NPs along with the major visible (and NIR) components of solar radiation passes unabsorbed to the solar cell. The extra visible (and NIR) radiation produced by the NPs contributes to the production of extra electricity thus increasing PV power conversion efficiency. The layer also blocks cosmic radiation and low-orbit atomic oxygen (AO) from reaching the solar cell.

The proposed polymer nanocomposite coating uses the NPs of a UV spectrum downshifting phosphor to absorb solar UV radiation and protect solar cells and re-emit visible and NIR light used in generating extra electric power and improve power conversion efficiency.

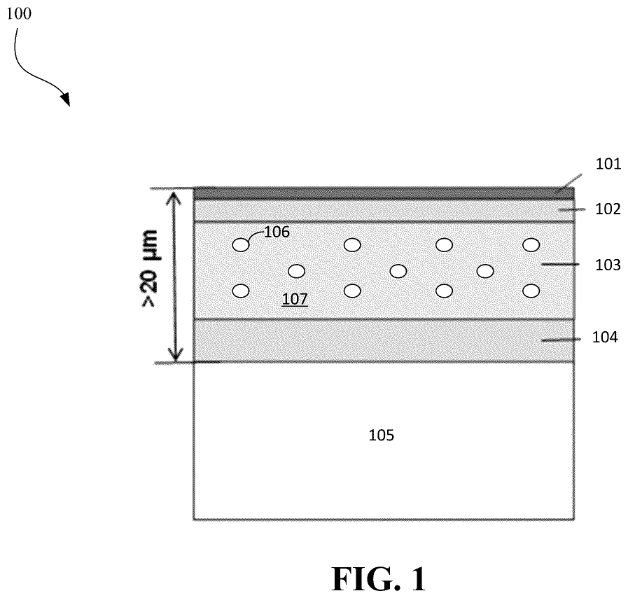

FIG. 1 is a diagram of an exemplary solar cell 100 in accordance with an embodiment of the present disclosure. The exemplary solar cell 100 comprises a photovoltaic cell (PV) 105. Further, the exemplary solar cell 100 comprises an anti-reflection coating layer 101, a nanocomposite layer 102, a polymer nanocomposite coating 103, and another nanocomposite layer 104.

In this regard, the first nanocomposite layer 104 is deposited on the PV cell 105. The first nanocomposite layer 104 blocks residual solar UV that has traveled through the top layers 101-103 from reaching the cell. Further, the first nanocomposite layer 104 additionally blocks AO from reaching the PV cell 105 and compromising operation of the PV cell 105. Note that in one embodiment, the second nanocomposite layer 102 may be CORIN-XLS, which is a fluorinated polyimide that has the highest light transmission and the capability of blocking oxygen plasma and atomic oxygen among all methionine sulfoxide reductases (MSRS) colorless polyimides. CORIN XLS Polyimide has a glass transition temperature of more than 250° C., making it suitable for many high temperature applications. Note that the CORIN XLS may be deposited using brushing, spin casting, spraying, drawing, and dipping.

The polymer nanocomposite coating 103 comprises spectrum converting nanoparticles 106 (NPs) embedded in a colorless polymer 107. Both ultraviolet (UV) and visible (and near infrared, NIR) radiation reach the polymer nanocomposite coating 103. The UV reaching the polymer nanocomposite coating 103 is absorbed by the NPs 106 and spectrally converted into visible (and NIR) radiation. The extra visible (and NIR) radiation produced by the NPs 106 along with the major visible (and NIR) components of solar radiation passes unabsorbed to the PV cell 105. The extra visible radiation produced by the NPs 106 contributes to the production of extra electricity thus increasing PV power conversion efficiency. The polymer nanocomposite coatings 102, 103, and 104 also block cosmic radiation and low-orbit atomic oxygen (AO) from reaching the solar cell.

In one embodiment, the nanoparticles (NPs) 106 of the polymer nanocomposite coating 103 are comprised of non-toxic spectral downshifting photoluminescent phosphor NaEuF₄. Fluoride NF₄ is a suitable host for rare-earth (RE) ions of Europium due to its low phonon energy (˜300 cm⁻¹) that minimizes multi-phonon assisted nonradiative relaxation of the excited Eu³⁺ ions. The Eu³⁺ ions are efficient spectrum converters in various inorganic matrices.

In one embodiment, the polymer 107 may be space-qualified polyurethane Optinox SR. Optinox SR is a two-part curable polymer host.

The second nanocomposite layer 102 is a colorless, clear, organic/inorganic nanocomposite that can be applied using brushing, spin casting, spraying, drawing, and dipping.

The second nanocomposite layer 102 is resistant to radiation and atomic oxygen erosion. The second nanocomposite layer 102 protects the polymer nanocomposite coating 103 and the PV cell 105 from AO with minimal blocking of UV and minimal UV-generated darkening (or yellowing). Note that in one embodiment, the second nanocomposite layer 102 may be CORIN-XLS, which is a fluorinated polyimide that has the highest light transmission and durability to oxygen plasma and atomic oxygen of all MSRS colorless polyimides. CORIN XLS Polyimide has a glass transition temperature of more than 250° C., making it suitable for many high temperature applications.

The anti-reflection coating 101 may be deposited atop the second nanocomposite layer 102. The anti-reflection coating 101 minimizes reflection losses of incident light. In one embodiment, the anti-reflection coating 101 is made of partial embedding of porous silica NPs into the surface of coating 102 will be used to make an anti-reflection agent The anti-reflection effect may be achieved by imprinting nanopores in the surface of polymer layer 102 by rolling a rod made of anodized aluminum.

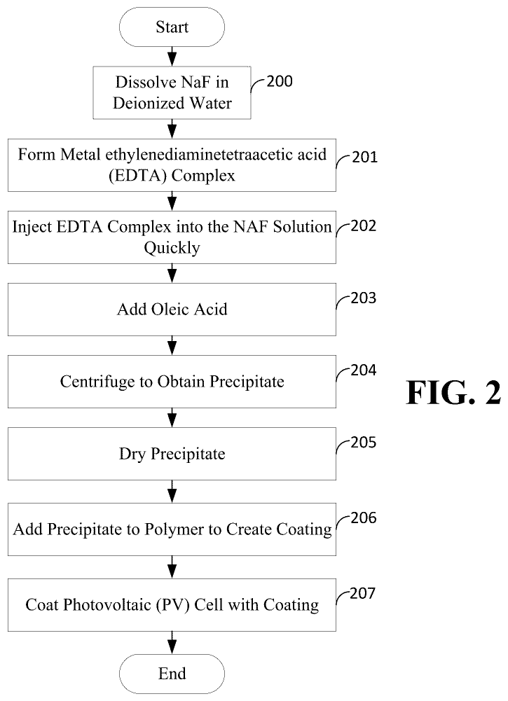

FIG. 2 is a flowchart of an exemplary method for making the polymer nanocomposite coating 103. In one embodiment, the NPs of NaEuF₄ compound may be synthesized using an economic wet process, which is a co-precipitation in the presence of Na₂-ethylenediaminetetraacetic acid (EDTA).

In step 200, NaF is dissolved in deionized water. In this regard, a first solution is formed using 2.1 g of NaF (0.05 mol) dissolved in 60 ml of the deionized water. In step 201, a metal ethylenediaminetetraacetic acid (EDTA) complex is formed. In this regard, the metal ethylenediaminetetraacetic acid (EDTA) complex comprises 16 mL of 0.2-mol/l solution of EuCl₃ and 20 mL of 0.2-mol/l EDTA aqueous stock solution.

In step 202, the EDTA complex is injected in the NaF/deionized water, and the mixture is stirred vigorously for 1 h at room temperature, forming a nano colloid. In step 203, oleic acid (0.1 mL) is added to the obtained nano colloid to prevent clustering of the NPs. In step 204, the nano colloid is centrifuged at 3500 rpm for 0.5 hour forming a supernatant liquid and a precipitate. The supernatant liquid is collected and discarded. In step 205, the precipitate is dried on a hot plate in the open air before transferring to an organic solvent.

In step 206, the precipitate is added to the polymer to create the coating. In step 207, the PV cell 105 (FIG. 1) is coated with the coating using one of the methods: brushing, spin casting, spraying, drawing, and dipping.

In one embodiment, the polymer used in step 206 is formed as follows. Optinox SR liquid mixture is prepared by adding between 8 and 9 g of Part B (as it was supplied by the manufacturer) to 90-110 g of Part A. In one embodiment, Part B is a Homopolymer of Hexamethylene Diisocyanate CAS #28182-81-2 95-100% by weight; Hexamethylene-1,6-Diisocyanate CAS #822-06-0, <=0.15% by weight, and Part A is a fluoropolymer 30-50% by weight; Xylene CAS #1330-20-7, 25-30% by weight; Ethylbenzene CAS #100-41-4, 20-30% by weight. In one embodiment, Part A is mixed while Part B is added. Between 1.3 and 2.1 g of the prepared nano-powder of NaEuF₄ was added to the mixture. Several mixing methods could be used for mixing the resin including propeller and impeller mixer, dispersion blade, rolling in a container or paint shaker, and magnetic stirrer. In the case of magnetic stirrer 100 to 150 rpm of rotation speed should be used. The material should have a uniform/homogeneous appearance at the conclusion of mixing step. For optimal coating results, the material should be allowed to set undisturbed for a period of 20-30 min following mixing to let bubbles dissipate form the resin. Parts A and B should be allowed to mix for at least 30 to 90 min before coating. The viscosity of the mixed resin should be conductive to most coating applications for approximately 12-16 hours. The viscosity of the material will slowly increase to the formation of gel within about 1-2 days after mixing of parts A and B.

The polymer created is mixed with the NPs, and the prepared mixture may be coated on a solar cell using brushing, spraying, spin casting, using blade, bar, or spiral applicators, and dip coating. After coating, the coating should be allowed to air dry until dry to the touch. Initial thermal curing should be conducted for 4-8 hours at a temperature of 80-90° C. Post cure heating to 40-50° C. for 10-12 hours is required to speed up the cure of the material.

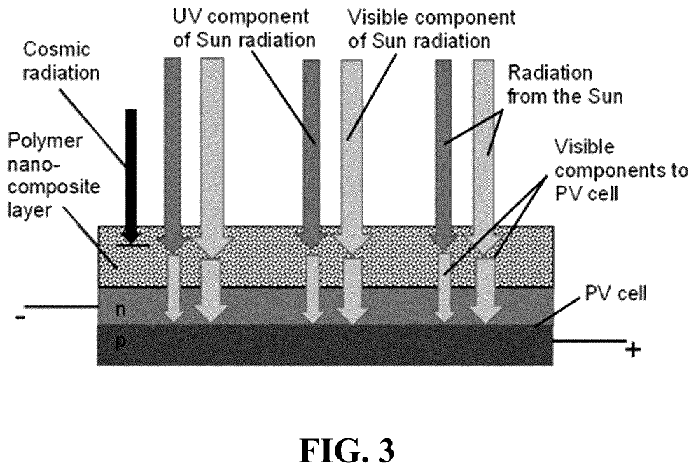

FIG. 3 is a diagram of the protective polymer nanocomposite coating 103. The design and the principle of operation of the protective coating is illustrated in FIG. 1. The polymer nanocomposite protective layer is made of spectrum converting nanoparticles (NPs) embedded in a colorless polymer. The layer is deposited on the top of a solar PV cell. Both UV and visible (and NIR) components of solar radiation reach the layer. The UV component is absorbed by the NPs and spectrally converted into visible (and NIR) radiation. The extra visible (and NIR) radiation produced by the NPs along with the major visible (and NIR) components of solar radiation passes unabsorbed to the solar cell. The extra visible radiation produced by the NPs contributes to the production of extra electricity thus increasing PV power conversion efficiency. The layer also blocks cosmic radiation and low-orbit AO from reaching the solar cell.

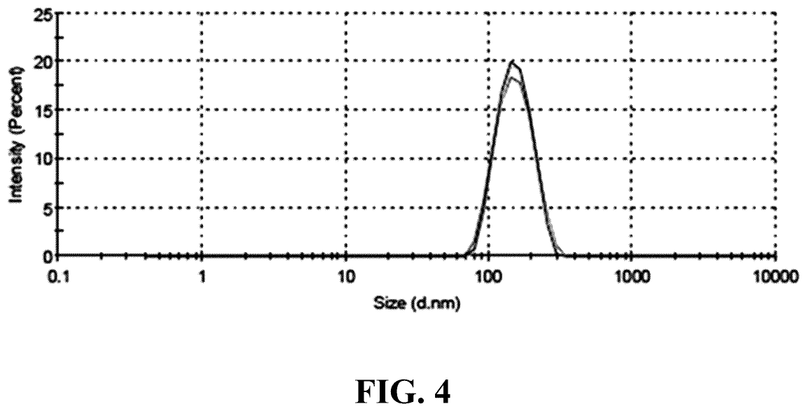

FIG. 4 is a graph showing dynamic light scattering (DLS) scans of the size distribution of the NPs 106 in diglyme. In one embodiment, the size of the NPs 106 (assuming their spherical shape) may be 154±40 nm.

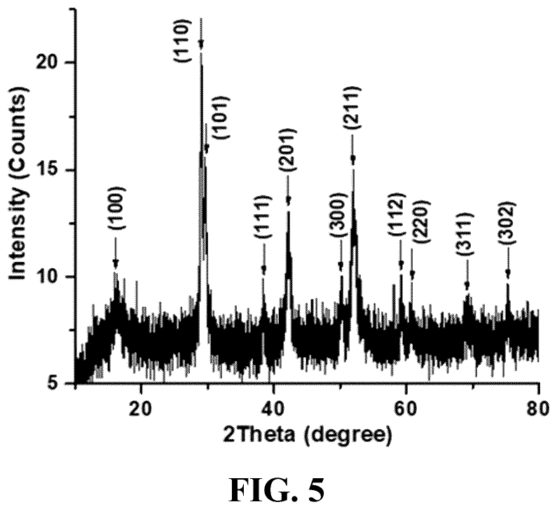

FIG. 5 illustrates the crystalline properties of the NPs 106 resulting from the use of X-ray diffraction (XRD) spectroscopy. In one embodiment, the NPs 106 may be investigated with a Bruker D2 Phaser X-ray powder diffractometer. The nano-powder did not change its crystalline phase after heating at 500° C. for several hours. This heat tolerance indicated that the coated solar panels would operate steadily in space where the temperature exceeds +120° C. (near Earth or on the Moon) or at higher temperatures (closer to the Sun or near Venus and Mercury due to their surface heating).

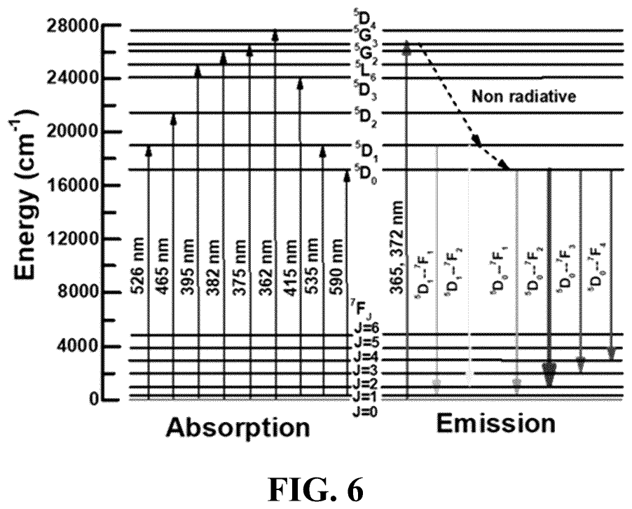

The mechanism of spectrum conversion in Eu³⁺ ions is downshifting as illustrated by the energy level diagram in FIG. 6. The left part of the diagram shows possible channels of excitation of the ions marked by vertical arrows up with corresponding wavelength values. The right part shows possible channels of relaxation of the excited ions marked with arrows down with corresponding transition formulae. After absorbing UV photons (for instance, with 372- or 365-nm wavelength), excited Eu³⁺ ions relax to lower energy levels and emit visible and NIR photons during the transition further down the energy ladder.

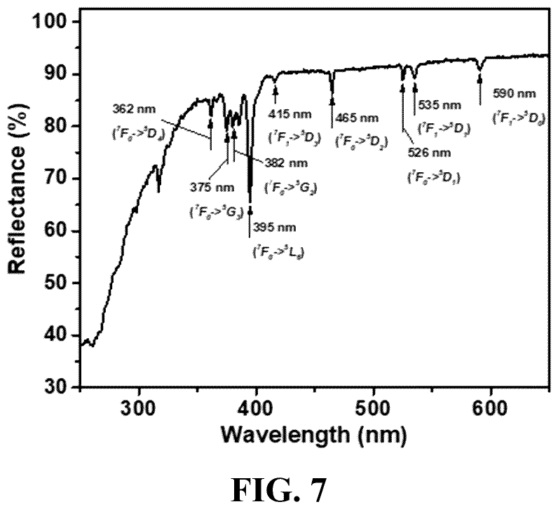

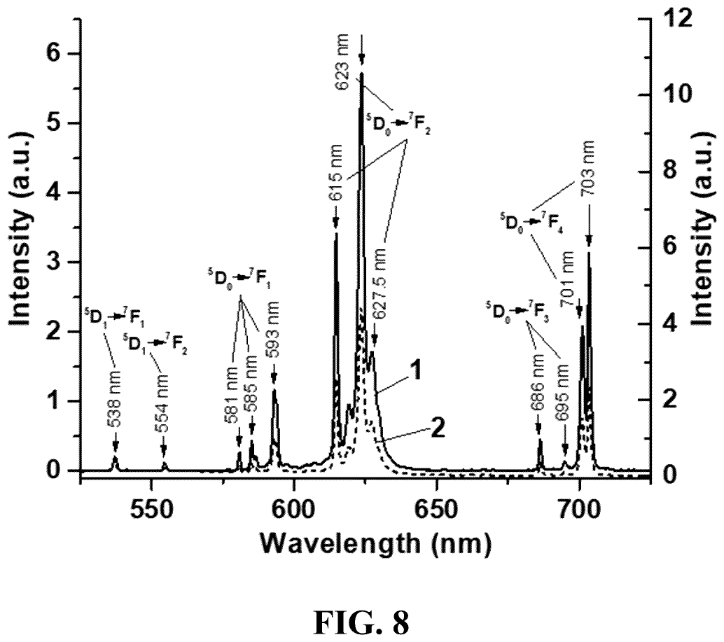

In one embodiment, the samples for optical spectroscopy measurements may be prepared by compressing the nano-powders into pellets using a 5-T hydraulic press. FIG. 7 presents the diffuse reflectance spectrum of a NaEuF₄ pellet sample measured with a Shimadzu UV-2600-ISR-2600 Plus UV-VIS-NIR spectrophotometer with an integrating sphere. The inverted absorption peaks can be attributed to the following excitation transitions of Eu³⁺ ions: ⁷F₀→⁵D₄ (362 nm), ⁷F₀→⁵G₃ (375 nm), ⁷F₀→⁵G₂ (382 nm), ⁷F₀→⁵L₆ (395 nm), ⁷F₁→⁵D₃ (415 nm), ⁷F₀→⁵D₂ (465 nm), ⁷F₀→⁵D₁ (526 nm), ⁷F₁→⁵D₁ (535 nm), and ⁷F₁→⁵D₀ (590 nm) shown in the left, “Absorption” part of the energy level diagram in FIG. 8. Photoluminescence (PL) spectroscopy of the nano-powders with a spectrometer AvaSpec-ULS4096CL-EVO with integrating sphere AvaSphere-30 from Avantes and a 372-nm UV diode laser LBX-375-70-CSB-PPA from Oxxius as a source of UV excitation generates a PL spectrum, as shown in FIG. 8, of (1) NaEuF₄ nano-powder sample pumped by a 372-nm UV diode laser Oxxius (71.3 mW/cm² irradiance) and (2) The polymer nanocomposite coating over a solar cell illuminated by a 365-nm UV LED (22.3 mW/cm² irradiance). The spectrum of the UV LED simulated the UV-A spectral component of sun radiation. PL peaks corresponded to the transitions of the excited Eu³⁺ ions to the lower energy states in accordance with the right, “Emission” part of the energy level diagram in FIG. 6. Dominant spectral peaks (at 615 and 623 nm) are in the band corresponding to transition ⁵D₀→⁷F₂. The maximum PL quantum yield (PLQY, the ratio of the number of visible-NIR photons to the number of exiting UV photons) of the nano-powder was estimated using the method described in as ˜69%. The PL spectrum of the polymer nanocomposite coating was like the spectrum of the phosphor itself. PLQY of the coating was estimated as ˜0.5%.

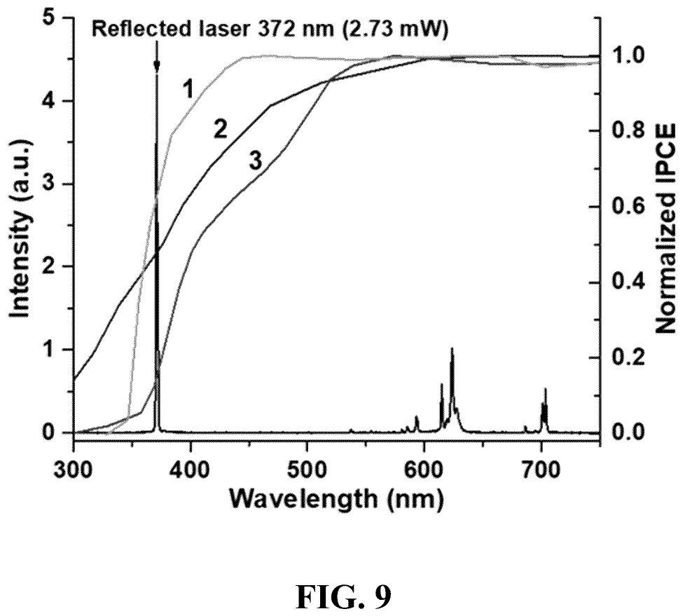

FIG. 9 shows the spectrum of the exciting UV laser reflected from the nano-powder pellet. The intensity of the major PL peak at 623 nm was ˜20% of the intensity of the laser peak (2.7-mW power). FIG. 9 also indicates that the PL spectrum well matches the spectra of the Incident-Photon-to-Current Efficiency (IPCE, also called External Quantum Efficiency or EQE) of three major types of solar cells potentially suitable for space missions: Silicon Heterojunction (SHJ) (curve 2), Copper-Indium-Gallium-Selenide (CIGS) (curve 3) and Inverted Metamorphic Multijunction (IMM) (curve 1).

1. A method of making a protective coating for a solar cell, comprising:
depositing a first polymer nanocomposite coating on a front surface of the solar cell;
depositing a second polymer nanocomposite coating on the top of the first polymer nanocomposite coating;
depositing a third polymer nanocomposite coating on the top of the second coating;
fabricating an optical anti-reflection coating on the third polymer nanocomposite coating.

2. The method of claim 1, further comprising depositing the first polymer nanocomposite coating having a thickness between 2 and 8.

3. The method of claim 1, further comprising depositing the first polymer nanocomposite coating made of a colorless polyimide.

4. The method of claim 1, further comprising depositing the second polymer nanocomposite coating made of a colorless polymer impregnated with the nanoparticles (NPs) of a spectrum converting compound absorbing solar UV radiation and re-emitting visible and near-infrared (NIR) radiation suitable for generating electricity by the solar cell via the photovoltaic effect.

5. The method of claim 5, further comprising depositing the second polymer nanocomposite coating comprising NPs made of Na EuF₄.

6. The method of claim 5, further comprising depositing the second polymer nanocomposite coating comprising NPs mixed with the colorless polymer at a proportion of between 1.3 and 2.1 grams to between 100 and 120 grams of the resin.

7. The method of claim 1, further comprising depositing the second polymer nanocomposite coating having a thickness between 10 and 20 microns.

8. The method of claim 1, further comprising depositing the first polymer nanocomposite coating made of a space qualified polyurethane.
The third polymer nanocomposite coating in claim 1 has a thickness of 1 to 5 micron.

9. The method of claim 1, further comprising fabricating the anti-reflection coating by partial embedding of porous silica NPs into the surface of the third coating.

10. The method of claim 1, further comprising fabricating the anti-reflection coating in claim by imprinting nanopores in the surface of polymer layer 102 by rolling a rod made of anodized aluminum.

11. A solar cell for use in space applications, comprising:
a first polymer nanocomposite coating deposited on a front surface of the solar cell;
a second polymer nanocomposite coating deposited on a top of the first polymer nanocomposite coating;
a third polymer nanocomposite coating deposited on a top of the second coating;
an optical anti-reflection coating fabricated on the third polymer nanocomposite coating.

12. The solar cell of claim 11, wherein the first polymer nanocomposite coating is made of a thickness between 2 and 8.

13. The solar cell of claim 11, wherein the first polymer nanocomposite coating is made of a colorless polyimide.

14. The solar cell of claim 11, wherein the second polymer nanocomposite coating is made of a colorless polymer impregnated with the nanoparticles (NPs) of a spectrum converting compound absorbing solar UV radiation and re-emitting visible and near-infrared (NIR) radiation suitable for generating electricity by the solar cell via the photovoltaic effect.

15. The solar cell of claim 14, wherein the second polymer nanocomposite coating comprises NPs made of Na EuF₄.

16. The solar cell of claim 15, wherein the second polymer nanocomposite coating comprises NPs mixed with the colorless polymer at a proportion of between 1.3 and 2.1 grams to between 100 and 120 grams of the resin.

17. The solar cell of claim 16, wherein the second polymer nanocomposite coating has a thickness between 10 and 20 microns.

18. The solar cell of claim 17, wherein the first polymer nanocomposite coating is made of a space qualified polyurethane.

19. The solar cell of claim 18, wherein the third polymer nanocomposite coating has a thickness of 1 to 5 micron.

20. The solar cell of claim 12, wherein the anti-reflection coating comprises partial embedded particles of porous silica NPs into the surface of the third coating.

21. The solar cell of claim 12, wherein the anti-reflection coating is comprised of imprinted nanopores in the surface of polymer layer 102 by rolling a rod made of anodized aluminum.
